(19) United States
(12) Patent Application Publication
(10) Pub. No.: US 2005/0189552 A1
(43) Pub. Date: Sep. 1, 2005

(54) Semiconductor light-emitting device

(76) Inventors: Nobuyuki Ikoma, Yokohama-shi (JP); Takahiko Kawahara, Yokohama-shi (JP); Masato Furukawa, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 11/020,662

(22) Filed: Dec. 27, 2004

(30) Foreign Application Priority Data
Dec. 26, 2003 (JP) 2003-433972

(51) Int. Cl. H01L 29/22

(52) U.S. Cl. 257/94

(57) ABSTRACT

A light-emitting device including an active region having a quantum well structure formed by a first barrier layer made of a first III-V compound semiconductor material that contains aluminum, gallium, indium, and arsenic, and a quantum well layer made of a second III-V compound semiconductor material. The device also includes a buried semiconductor region provided on sides of the quantum well layer. The first III-V semiconductor material has a band gap wavelength greater than 1 μm.

### BACKGROUND OF THE INVENTION

1. Field of the Invention

The present invention relates to a semiconductor light-emitting device.

2. Related Prior Art

The Japanese patent published as 2000-286508 has disclosed a semiconductor layer that has an optical waveguide having a lower cladding layer, a core layer, a first upper cladding layer and a second upper cladding layer sequential stacked in this order and a channel including the fist upper cladding layer and the core layer is formed. This channel is buried by a lower burying layer and an upper burying layer. The core provides, on the lower cladding layer, a lower SCH (Separated Confinement Hetero-structure) layer made of InGaAsP, a hole stopping layer, an active layer made of AlGaInAs, whose emitting wavelength is within the 1.3 μm band, an electron stopping layer, and an upper SCH layer made of InGaAsP, these layers are stacked in this order. The semiconductor laser thus configured, since the aluminum content in the channel is small, the native oxide film of aluminum may be restricted, thereby enhancing the injection efficiency of carriers and providing a semiconductor device suitably operating in high temperatures and easily manufacturing.

IEEE Journal of Quantum Electronics, Vol. 25, No. 6 (1989) has analyzed of a leak current at high temperatures of a semiconductor laser with a buried hetero-structure of InGaAsP/InP. This laser provides a pnpn-type current blocking structure.

Inventors of the present invention manufactured a semiconductor laser that includes an active layer of AlGaInAs with a band gap wavelength of 1.8 μm band and buried with n-type InP/p-type InP. However, they could not obtain an estimated optical output from the laser. This may be caused by the leak current flowing in the buried layer. On the other hand, the laser diode having the buried hetero structure made of InGaAsP/InP has realized the small enough leak current.

The present invention, in view of subjects above mentioned, is to provide a light-emitting device that has the active layer containing AlGaInAs, in particular, to provide the laser that emits light, a wavelength of which is within 1.3 μm band, and includes the quantum well layer made of AlGaInAe, to reduce the leak current.

### SUMMARY DE THE INVENTION

According to one feature of the present invention, the light-emitting device provides: (a) an active region including a first barrier layer made of a first III-V compound semiconductor material containing aluminum, gallium, indium and arsenic, a and a quantum well layer made of second III-V compound semiconductor material, (b) buried semiconductor region provided on sides of the active region, and the first III-V compound semiconductor material has a band gap wavelength longer than 1.0 μm.

Because the light-emitting device of the present invention has the first barrier layer whose band gap energy is smaller than that corresponding to 1.0 μm, the injection of the minority carrier, electrons in this case, to the buried semiconductor region, p-type in this case, may be decreased, thereby reducing the leak current flowing in the buried semiconductor region.

The first III-V compound semiconductor material of the present light-emitting device may have the band gap wavelength longer than 1.05 μm.

Since the light-emitting device thus configured has the barrier layer made of the first III-V compound semiconductor material whose band gap wavelength is longer than 1.06 μm, the leak current may be decreased in the buried semiconductor layer.

The second III-V compound semiconductor material may include aluminum, gallium, indium and arsenic.

The constituent elements of the first III-V compound semiconductor material may be the same as those of the second III-V compound semiconductor material.

The light-emitting device of the present invention may provide: (c) a buried semiconductor layer with a first conduction type disposed on said buried semiconductor region, and the buried semiconductor region may have a second conduction type.

The light-emitting device thus configured has the buried region comprised of the buried semiconductor layer with the first conduction type and the buried semiconductor layer with the second conduction type, and provided between the III-V compound semiconductor region with the first conduction type and the III-V compound semiconductor region with the second conduction type. Therefore, the buried region, the III-V compound semiconductor region with the first conduction type and the III-V compound semiconductor region with the second conduction type form a thyristor. However, since the minority carrier injection, electrons in this case, into the buried semiconductor region, p-type in this case, may be reduced, the thyristor is prevented from turning on and the leak current flowing through the buried region may be restricted.

In the light-emitting device of the present invention, the buried region with the first conduction type may be made of III-V compound semiconductor material containing indium and phosphorous, while the buried semiconductor layer with the second conduction type may be made of III-V compound semiconductor material containing indium and phosphorous.

The injection of the minority carrier, electrons in this case, may be reduced to the buried semiconductor region, which is made of p-type III-V compound semiconductor material containing indium and phosphorous, in contact with the first barrier layer, which is made of III-V compound semiconductor material containing aluminum, gallium, indium and arsenic.

The light-emitting device of the present invention may further comprise: (d) a III-V compound semiconductor region with the first conduction type, (e) a III-V compound semiconductor region with the second conduction type. The active region and the buried region are disposed on the III-V compound semiconductor region with the first conduction type, and the III-V compound semiconductor region with the second conduction type is disposed on the active region and the buried region. The active region may include one or more second barrier layers, and the first barrier layer may position nearest to the III-V compound semiconductor laser with the first conduction type.

The light-emitting device of the present invention may further include: (d) a III-V compound semiconductor layer with the first conduction type, (e) a III-V compound semiconductor layer with the second conduction type. The active region and the buried region are disposed on the III-V compound semiconductor region with the first conduction type. The III-V compound semiconductor layer may be disposed on the active region and the buried region. The active region may further include an SCH layer provided between the III-V compound semiconductor layer with the first conduction type and the quantum well layer. The band gap wavelength of the SCH layer may be smaller than that of the barrier layer.

The light-emitting device of the present invention may further provide: (d) an InP substrate with the first conduction type, (e) a cladding layer made of InP with the first conduction type and disposed on the InP substrate, (f) a cladding layer made of InP with the second conduction type and disposed on the InP substrate, and (g) a III-V compound semiconductor layer made of InP with the second conduction type and disposed on the buried region and on the cladding layer with the second conduction type. The active region is disposed between the cladding layer with the first conduction type and the cladding layer with the second conduction type. The active region, the cladding layers with the first and the second conduction type are disposed on the InP substrate. The quantum well layer may be made of AlGaInAs and the first barrier layer may be made of AlGaInAs.

According to the light-emitting device of the present invention, preferred embodiments are provided and the buried region preferably provides the InP layer with the first conduction type and the InP layer with the second conduction type. On the active region is provided with the InP buried layer with the second conduction type.

In the light-emitting device of the present invention, the first III-V compound semiconductor material may have a band gap wavelength shorter than 1.15 μm.

According to the first III-V compound semiconductor material for the barrier layer, a barrier may be realized with enough barrier height against the quantum well layer.

The light-emitting device of the present invention preferably provides: (a) an active region including the quantum well structure comprising of the first barrier layer made of the first III-V compound semiconductor material containing aluminum, gallium, indium and arsenic, and the quantum well layer made of the second III-V compound semiconductor material, (b) a buried semiconductor region including the buried semiconductor layer with the first conduction type and the buried semiconductor layer with the second conduction type and formed on the sides of the active region, (c) a III-V compound semiconductor region with the first conduction type, and (d) a III-V compound semiconductor region with the second conduction type. The active region and the buried region are disposed on the III-V compound semiconductor layer with the first conduction type, and the sides of the active region provides the p-type buried semiconductor layer. The band gap energy of the first III-V compound semiconductor material is smaller than that corresponding to 1.0 μm. According to the light emitting device thus configured, since the band gap energy of the first III-V compound semiconductor material is smaller than that corresponding to 1.0 μm, the injection of the minority carrier, electrons in this case, may be reduced, thereby preventing the pnpn thyristor including the buried semiconductor layer from turning on and the leak current from increasing.

The objects, features and advantages of the present invention above mentioned will be easily understood from the detailed description recorded below of preferred embodiments of the invention, which are carried out by referring to accompanying drawings.

As mentioned above, according to the present invention, a light-emitting device is provided, in which the active region including a layer made of AlGaInAs and the leak current may be reduced.

### BRIEF DESCRIPTION OF DRAWINGS

FIG. 1A is a perspective view showing a first embodiment of the present invention, and FIG. 1B shows an active region of the light-emitting device shown in FIG. 1A;

FIG. 2A shows the light-emitting device of the first embodiment, and FIG. 2B and FIG. 2C show calculated results of the band discontinuity based on a ratio of the band discontinuity of the conduction band to that of the valence band (ΔEc:ΔEv=0.4:0.6) for the InGaAsP/InGaAs system lattice matched to InP, and the ratio (ΔEc:ΔEv=0.72:0.28) for the AlGaInAs/InGaAs system lattice matched to InP;

FIG. 3A shows a model for the simulation, FIG. 3B shows a fine structure of the active region for the simulation and FIG. 3C shows a fine structure of the light-emitting device for the simulation;

FIG. 4 shows a result of the simulation for the leak current;

FIG. 5 shows a result of the simulation for the differential gain;

FIG. 6A shows a modification of the preferred embodiment, and FIG. 6B shows another modification of the embodiment;

from FIG. 7A to FIG. 7C show a method for manufacturing the light-emitting device according to the second embodiment of the invention; and

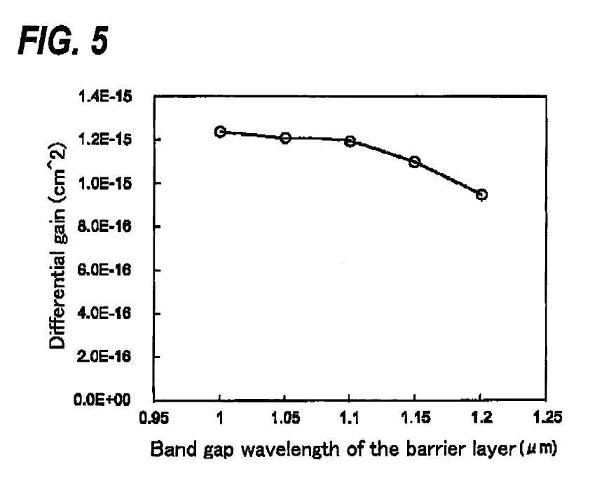

from FIG. 5A to FIG. 8C show a method for manufacturing the light-emitting device subsequently to FIG. 7C according to the second embodiment of the invention.

### DETAILED DESCRIPTION OF PREFERRED EMBODIMENTS

Subjects of the present invention will be easily understood by referring to accompanying drawings with considering the specification recorded hereof. Next, embodiments according to the present light-emitting device of the present invention will be explained as referring to accompanying drawings, In the specification, if possible, same elements will be referred by same symbols.

### First Embodiment

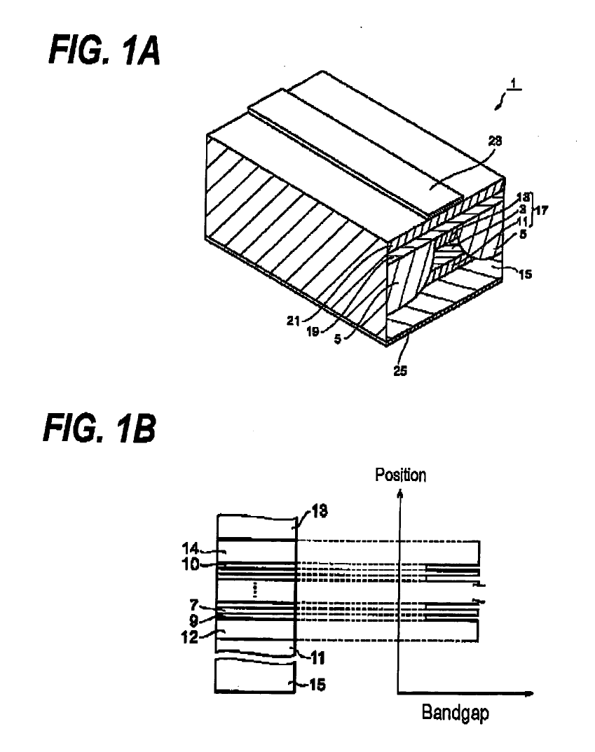

FIG. 1A shows a semiconductor light-emitting device according to the first embodiment of the present invention. FIG. 1B shows an active region of the semiconductor light-emitting device shown in FIG. 1A.

The semiconductor light-emitting device 1 provides an active region 8 and a buried region 6. The buried region 5 is provided on sides of the active region 3. The active region 9 includes a first barrier layer 7 and a quantum well structure including a quantum well layer 9. The first barrier layer 7 is comprised of a first III-V compound semiconductor material that includes aluminum (Al), gallium (Ga), indium (In) and arsenic (As). The quantum well layer 9 is comprised of second compound semiconductor material. The first compound semiconductor material may have a band gap wavelength longer than 1 μm. In the present light-emitting device 1, the band gap of the first barrier layer 7 is smaller than the energy gap corresponds to the wavelength of 1 μm. Accordingly, the minority carrier injection, electrons in the present configuration, into the buried layer 5, which is a p-type material, can be decreased, thereby reducing a leak current flowing in the buried region.

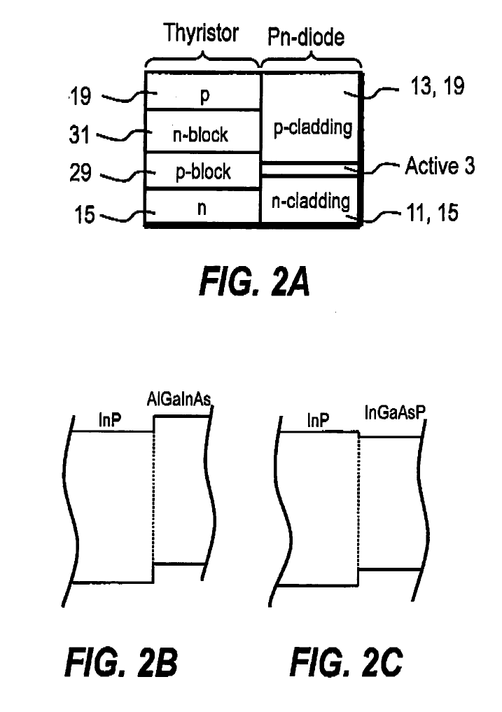

Describing in detail as referring to FIG. 2A, the light-emitting device 1 further includes, in addition to the active region 8 and the buried region 5, an n-type semiconductor layer 11 and a p-type semiconductor layer 18. The buried region 5 buries a stripe 17 that includes the active region 8, the n-type semiconductor layer 11 and the p-type semiconductor layer 13, Further, the light-emitting device 1 may provide a semiconductor substrate 15 made of, for example, InP. The buried region and the stripe are formed on the substrate 15. The light-emitting device 1 further includes a p-type semiconductor layer 19 provided on the buried region 6 and the stripe 17. The buried region 6 includes a p-type buried semiconductor layer 29 and n-type buried semiconductor layer 31. The p-type buried semiconductor layer 31 is provided on sides of the active region 8 and the n-type semiconductor layer 11, and on the substrate 16. The n-type semiconductor layer 15, the p-type buried semiconductor layer 29, the n-type buried semiconductor layer 31 and the p-type semiconductor layer 19 configures a pnpn thyristor structure. In the light-emitting device 1, since the first barrier layer 7 is made of a III-V compound semiconductor material with the band gap energy thereof smaller than that corresponding to 1 μm, the minority carrier (electrons) injection into the p-type buried semiconductor layer 29 adjacent to the active region 5 can be reduced, thereby suppressing the increase of the leak current due to the thyristor structure being turned on.

In the preferred embodiment, the first III-V compound semiconductor material applied in the first barrier layer 7 preferably has a band gap wavelength longer than 1.05 μm. According to thus configured light-emitting device 1, since the first III-V compound semiconductor material has the band gap wavelength longer than 1.05 μm, the leak current flown in the buried region can be reduced.

In the light-emitting device 1, the second III-V compound semiconductor material may include aluminum (Al), gallium (Ga), indium (In) and arsenic (As). The band gap wavelength of the second III-V compound semiconductor material applied to the quantum well layer 9 is longer than the that of the first III-V compound semiconductor material. For instance, the band gap wavelength of the second III-V compound semiconductor material is 1.4 μm.

The light-emitting device 1 further includes a semiconductor layer 11 having a first conduction type and another semiconductor layer 18 having a second conduction type. The semiconductor layer 11 and the other semiconductor layer 13 operate to confine carriers into the active region 3. In the preferred embodiment, the active region 3, the semiconductor layer 11 with the first conduction type, and the other semiconductor layer with the second conduction type form the strips 17. The buried region 6 buries the stripe 17. The light-emitting device 1 further includes the substrate 16. The buried region 6 and the stripe 17 are formed on the substrate 15. The light-emitting device 1 may further provide a semiconductor layer 19 with the second conduction type formed on the stripe 17, and a contact layer 21 with the second conduction type. On the contact layer 21 is provided an electrode 28, while on the back surface of the substrate 15 is formed another electrode 26. In an exemplary arrangement, the buried region 5 may include an n-type InP and a p-type InP. The p-type InP is provided on the substrate 15, while the n-type InP is formed on the p-type InP.

In the light-emitting device 1, the active region 9 and the buried region 5 are formed on the III-V compound semiconductor material with the first conduction type. On the active region band the buried region 5 are provided with the III-V compound semiconductor layers 18 and 19 with the second conduction type.

Illustrating an exemplary configuration of the light-emitting device 1:

Active region 3

| | |
|---|---|
| first barrier 7: | undoped AlGaInAs |
| quantum well layer 9: | undoped AlGaInAs |
| | (band gap wavelength is 1.4 μm, |
| | emitting wavelength from the |
| | quantum well 1.3 μm) |
| buried region 5: | n-type InP 31/p-type InP 29 |

semiconductor layer with the first conduction type 11; n-InP
semiconductor layer with the second conduction type 13: p-InP
substrate 16: n-InP
semiconductor layer with the second conduction type 19: p-InP
contact layer with the second conduction type 21: p-InGaAs
first electrode 28: anode electrode
second electrode 25: cathode electrode

The background of the present invention will be described. A light-emitting device capable of modulating by a higher frequency with a low cost is demanded as the capacity of the optical communication expands. A semiconductor laser with a oscillation wavelength around 1.3 μm, which is directly modulated by an electrical signal without any temperature control thereof, is paid attention to meet such demand. Because of no temperature controlling means, it is inevitable to show an excellent characteristic itself at high temperatures, and a compound of AlGaInAs material, which enables to enhance the temperature characteristic of the laser diode, is preferable to use for the active layer instead of InGaAsP that is conventionally applied for the active layer. A semiconductor laser diode with a buried region, which is formed by (1) growing the active layer on the InP substrate, (2) etching the grown layers to form a mesa stripe, and (9) burying the mesa stripe with an InP blocking layer, shows a low threshold current characteristic and a stable transverse mode because, due to the blocking layer, the current provided thereto is effectively confined within the active layer. A combination of an n-type InP and a p-type InP is used for the blocking layer.

The Japanese Patent 1, which is previously referred, has disclosed a buried semiconductor laser diode that includes p and n-blocking layers using the p-type InP for the lower buried layer and the n-type InP for the upper buried layer. However, this reference has not mentioned or suggested about an arrangement to decrease the leak current flowing in the p- and n-blocking layers.

Next, methods to reduce the leak current, which is recorded in references previously listed, will be described. The structure of the laser having the p- and n-blocking layers to confine the current is regarded as a thyristor having a pnpn layer structure attaches to the pn diode. A structure where the n-blocking layer does not come in contact with the n-cladding layer is essential to reduce the leak current. Therefore, the p-cladding layer and the p-blocking layer are formed to come in contact. In order to decrease the current flowing from the p-cladding layer to the n-layer via the p-blocking layer, it is preferable to narrow the region where the p-cladding layer comes in contact with the p-blocking layer. Further, the references has recorded that it is effective for decreasing the leak current to raise the potential barrier for the minority carrier by increasing the doping concentration of the p- and n-blocking layers. This is due to the increase of the leak current flowing via the p- and n-blocking layers by turning the thyristor when the minority injected into the blocking layer carrier (electrons for the p-blocking layer and holes for the n-blocking layer) increases. Semiconductor lasers appeared in prior patents, the active layer is formed to come in contact with the p-blocking layer. However, how the arrangement of the active layer affects the leak current flowing in the blocking layer has not mentioned at all.

Next, advantages of the present embodiment of the present invention will be described as comparing an arrangement, in which the active layer includes a quantum well with a InGaAsP barrier layer, to an arrangement where the active layer includes a quantum well with an AlGaInAs barrier layer. FIG. 23 and FIG. 2C show calculating results of the band 1o discontinuity using a value of ΔEc:ΔV=0.4/0.6 in FIG. 2B, which is typically used as the band discontinuity ratio of the conduction band to that of the valence band of InGaAsP/InGaAs, both lattice matched to InP substrate, and another value of ΔEc:ΔV=0.72/0.28 in FIG. 2C typically used for the AlGaInAs/InGaAs lattice matched to InP substrate. In InP/InGaAsP system, the conduction band is lower by 7.0×10²¹ joule (44 meV) in InGaAsP, while in InP/AlGaInAs system, the conduction band is higher by 1.88×10²⁰ joule (106 meV) in AlGaInAs. The active layer of the light-emitting device generates light by injecting electrons and holes therein. In the case of the quantum well structure, light is generated in the quantum well layer, while electrons are injected through the conduction band of the barrier layer.

From the view point of decreasing the leak current, the p-blocking layer is formed to come in contact with the sides of the active layer. Since the band discontinuity between the barrier layer and the InP layer is as shown in FIG. 2, electrons are hard to be injected into the InP from the conduction band of the barrier layer when the barrier layer is made of InGaAeP. On the other hand, when the barrier layer is made of AlGaInAs, electrons are injected into the InP layer from the conduction band of the barrier layer.

When the injection of electrons into the p-type blocking layer, which become minority carriers therein, the pnpn thyrietor turns, thereby increasing the leak current, When the barrier layer is made of AlGaInAs, it is considered that the injection of electrons from the barrier layer into the p-type InP blocking layer increase, thereby increasing the leak current. In the present invention, the band gap of the barrier layer is smaller than that corresponding to 1.0 μm. To decrease the band gap of the barrier layer, the level of the conduction band shifts to the lower energy, which also decreases the injection of electrons from the barrier layer into the p-type InP blocking layer, Therefore, the pnpn thyristor is restricted from turning on, and the leak current decrease even when the greater current is applied to the device. When the barrier layer is made of InGaAsP, the subject above described is not necessary to be a problem.

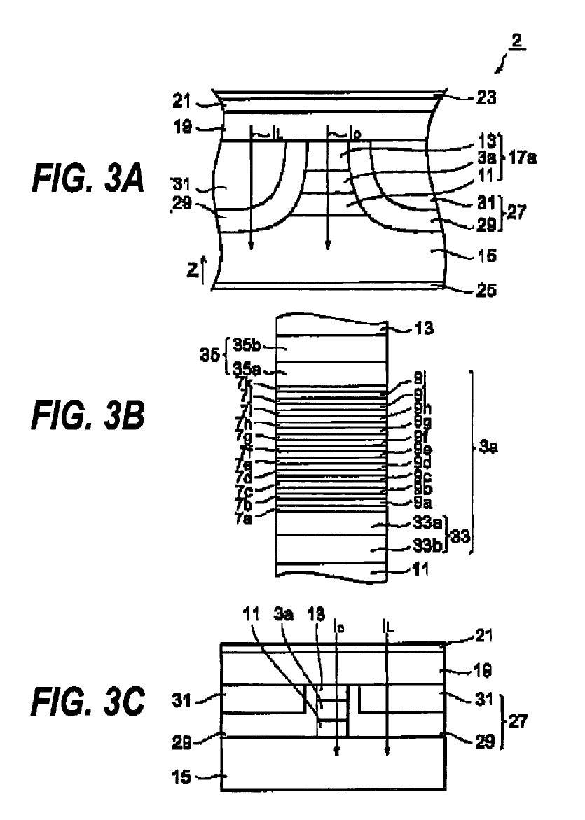

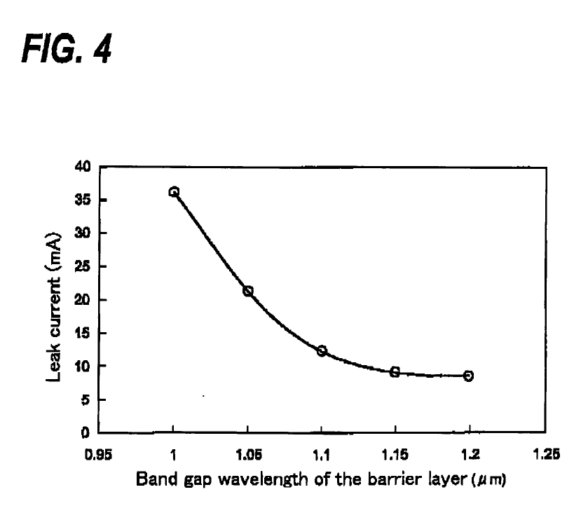

FIG. 8A is shows a simulation model of the light-emitting device, FIG. 4B shows a structure of an active region of the device, and FIG. 3C shows in detail of the simulation model of the light-emitting device. In the simulation, respective semiconductor layers are approximated to be substantially rectangle for the sake of the simulation. In FIG. 9A, the current ID flows in the stripe 17, while the current IL denotes the leak current flowing in the buried region.

In FIG. 8A, the buried region 27 and the mesa stripe 17a are formed on the substrate 15. The buried region 27 includes a layer 29 having a second conduction type, p-type InP in FIG. BA, and another layer 81 having a first conduction type, n-type InP in FIG. 5A. The layer 29 is formed on the substrate and sides of the mesa stripe 17a. The mesa stripe 17a includes an active region 3a between a layer 11 having the first conduction type and another layer 13 having the second conduction type. The active region 8a, as shown in FIG. 5B, a plurality of barrier layers from 7a to 7i and a plurality of well layers from 9a to 9j. The barrier layers 7a to 7i and well layers 9a to 9j are alternately formed to each other. The oscillation wavelength of the well layers are set to be, for instance, 18 μm. Between the layer 11 of the first conduction type and the well layer 9a is provided with an separated optical confinement (SCH) layer 38, similarly, another SCH layer 85 is provided between the layer 18 of the second conduction type and the well layer 9j. The SCH layer 33 may include an undoped SCH layer 33a and a layer 33b of the first conduction type, while the other SCH layer 95 may include an undoped SCH layer 35a and the other layer 85b of the second conduction type.

Conditions for the simulation are listed below:

SCH Layer 33

undoped SCH layer 88a
   material; undoped AlGaInAs
   band gap wavelength: same with that of the barrier layer
   thickness: 82 nm
first conduction type SCH layer 33b:
   material: n-type AlGaInAs
   band gap wavelength: 1.0 μm
   thickness: 40 nm
   carrier concentration: 8×10¹⁷ cm's
      SCH layer 35
undoped SCH layer 35a:
   material: undoped AlGaInAs
   band gap wavelength: same with that of the barrier layer
   thickness: 82 nm
second conduction type SBCH layer 35b:
   material: p-type AlGaInAs
   thickness; 40 nm
   carrier concentration: 8×10¹⁷ cm⁻³
quantum well layers 9a˜9j:
   material: undoped AlGaInAs
   band gap wavelength: 1.4 μm
   thickness: 5 nm
barrier layers 7a˜7j:
   material: undoped AlGaInAs
   band gap wavelength: from 1.0 to 1.25 μm with 0.05 μm step for the simulation
   thickness: 8 nm
first conduction type layer 11:
   material: n-type InP
   carrier concentration: 1×10¹⁸ cm⁻⁸
   thickness: 0.9 μm
second conduction type layer 18:
   material: p-type InP
   carrier concentration: 1×10¹⁸ cm⁻⁵
   thickness: 0.8 μm
buried layer with second conduction type 29:
   material: p-type InP
   carrier concentration: 1×10¹⁸ cm⁻⁸
   thickness: 1.0 μm
buried layer with first conduction type 31:
   material: n-type InP
   carrier concentration: 1×10¹⁸ cm⁻³
   thickness: 1.0 μm
   (A gap of 0.1 μm is formed between the active region and the n-type InP layer)
buried layer with first conduction type 16:
   material: n-type InP
   carrier concentration: 1×110¹⁶ cm⁻⁸
   thickness: 5.0 μm
second conduction type layer 19:
   material: p-type InP
   carrier concentration: 1×10¹⁸ cm⁻⁸
   thickness: 1.2 μm
contact layer with second conduction type 21:
   material: p-type InGaAs
   carrier concentration: 1×10¹⁹ cm⁻⁸
   thickness: 0.65 μm
      The lattice mismatching (Δa/a) between the quantum well layer of undoped AlGaInAs (in which the band gap wavelength of around 1.4 μm is so adjusted for the oscillation wavelength to be 1.8 μm) and InP layers is about +1% and is compressive for the quantum well layers.

FIG. 4 shows a behavior of the leak current against the band gap wavelength of the barrier layer. The horizontal axis denotes the band gap wavelength of the AlGaInAs barrier layer, while the vertical axis denotes the leak current when the bias current of 100 mA is applied to the active region. In FIG. 4, when the band gap wavelength of the AlGaInAs barrier layer is greater than 1.0 μm, the leak current drastically decreases. When the band gap wavelength of the AlGaInAs barrier layer becomes further greater than 1.15 μm, the rate of the change becomes gradual. Therefore, to apply the barrier layer with the band gap wavelength greater than 1.0 μm, which is equivalent to the case that the band gap of the barrier layer becomes smaller, the leak current may be decreased. To use the barrier layer with the band gap wavelength greater than 1.05 μm, the leak current may be reduced by about 60% of the case that the band gap wavelength of the barrier layer is 11.0 μm. When the band gap wavelength of the barrier layer is greater than 1.1 μm, the leak current may be reduced by about 35% of the case that the band gap wavelength of the barrier layer is 1.0 μm.

FIG. 5 shows a differential gain calculated by the condition described above. The horizontal axis corresponds to the band gap wavelength of the AlGaInAs barrier layer in micron meter, while the vertical axis denotes the differential gain of the light-emitting device in square centimeter. As shown in FIG. 5, in the region that the band gap wavelength of the barrier layer is smaller than 1.1 μm, the differential gain of the device shows substantially flat value over 1.2×10⁻¹⁵ cm². When the band gap wavelength of the barrier layer exceeds 1.1 μm, the differential gain starts to decrease from 1.2×10¹⁶ cm² and becomes about 1.1×10⁻¹⁵ cm⁻³ at 1.15 μm of the band gap wavelength of the barrier layer. In the case that the band gap wavelength of the barrier layer is greater than 1.2 μm, the differential gain reduces to about 9.6×10⁻¹⁶ cm⁻².

In the semiconductor laser having the active layer with lo the quantum well layer of AlGaInAs and the buried region including p-type and n-type InP layers, the oscillation wavelength of which is within 1.3 μm band, it is preferable that the band gap wavelength of the barrier layer is greater than 1.06 μm from the viewpoint of the leak current, while it is also preferable that the band gap wavelength of the barrier layer is smaller than 1.15 μm from the viewpoint of the differential gain thereof. The band gap wavelength of the barrier layer thereof is preferably about 1.1 μm in to cope with both the leak current and the differential gain. When the greater differential gain is necessary depending on the application of the laser, the band gap wavelength of the barrier layer is preferably about 1.05 μm. On the other hand, when the smaller leak current is required, the band gap wavelength of the barrier layer should be preferably about 1.15 μm.

Making the band gap wavelength of the AlGaInAs barrier layer longer, the leak current of the light-emitting device may be reduced. When the band gap wavelength thereof is over 1.05 μm, the leak current can be further decreased by providing the SCH layer with the band gap wavelength of about 1.0 μm between the cladding layer, for instance made of InP, and the barrier layer.

The light-emitting device 1, thus described in the foregoing specification, provides the active region including a quantum well structure formed by the first barrier layer 7, which contains the first III-V compound semiconductor material with a composition of aluminum, gallium, indium and arsenic, and the quantum well layer 9, which contains the second III-V compound semiconductor material, the buried region 5 formed on both aides of the active region 8 and include the p-type buried layer 29 and the n-type buried layer 81, a plurality of p type III-V compound semiconductor layers of 13, 19 and 21, and a plurality of n-type compound semiconductor layers of 11 and 15. The active region 8 and the buried region 6 are disposed on so the n-type III-V compound layer 11 and 15. The p-type III-V compound layers, 13, 19 and 21 are disposed on the active region 8 and on the buried region B. On the sides of the active region 8 are provided with the p-type buried layer 29. The band gap energy of the first III-V compound semiconductor material, which composes the first barrier layer 7, is smaller than that corresponds to the wavelength of 1 μm. Therefore, the injection of the minority carrier, which is the electron in this case, into the p-type buried layer 29 may be reduced, thereby preventing the pnpn thyristor, which is comprised of the semiconductor layers of 19, 31, 29 and 15, from turning on and the leak current from increasing.

Accordingly, the light-emitting device may be provided, in which the active region includes AlGaInAs, in particular, the active region includes the quantum well structure made of AlGaInAs with the emitting wavelength of 1.3 μm band, and the leak current can be reduced.

An embodiment of the present invention provides a semiconductor laser with a configuration of the buried layer having the reverse-biased pn junction with a good temperature characteristic and with reduced leak current flowing through the InP blocking layers. In this semiconductor laser, the active layer has the quantum well structure made of AlGaInAs, the barrier layer of which has the band gap wavelength longer than 1.0 μm. That is, the semiconductor light-emitting device of the present invention provides the active region that includes the barrier layer of AlGaInAs, the semiconductor layer having the first conduction type disposed on the active region, the semiconductor layer having the second conduction type disposed under the active region, and the buried semiconductor layer comprising the first and second conduction type to concentrate the current into the active region. Moreover, the band gap energy of the barrier layer of AlGaInAs is smaller than that corresponding to the wavelength of 1.0 μm.

Referring to FIG. 1, in the light-emitting device 1, the active region 3 and the buried region 5 are disposed on the III-V compound semiconductor regions 11 and 16 with the first conduction type. The III-V compound semiconductor layer 1i and 19 are disposed on the active region 3 and the buried region 5. The active region 8 further includes the optical confinement layer 12 between the III-V compound semiconductor region 15 with the first conduction type and the quantum well layer 9. The band gap wavelength of the confinement layer 12 is smaller than that of the barrier layer 7. Using the confinement layer 12, the band gap wavelength of which is smaller than that of the barrier layer, the leak current may be further decreased. Moreover, the active region 3 may provide anther optical confinement layer 14 between the III-V compound semiconductor regions 18 and 19 with the second conduction type and the quantum well layer 10.

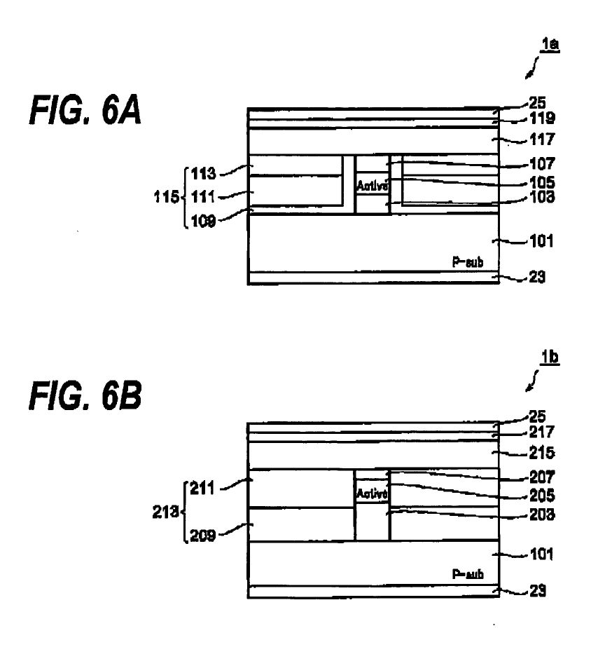

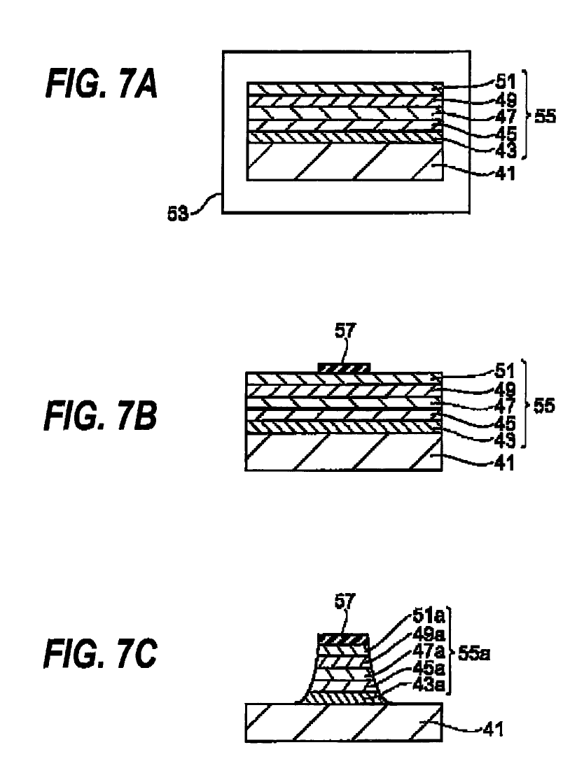

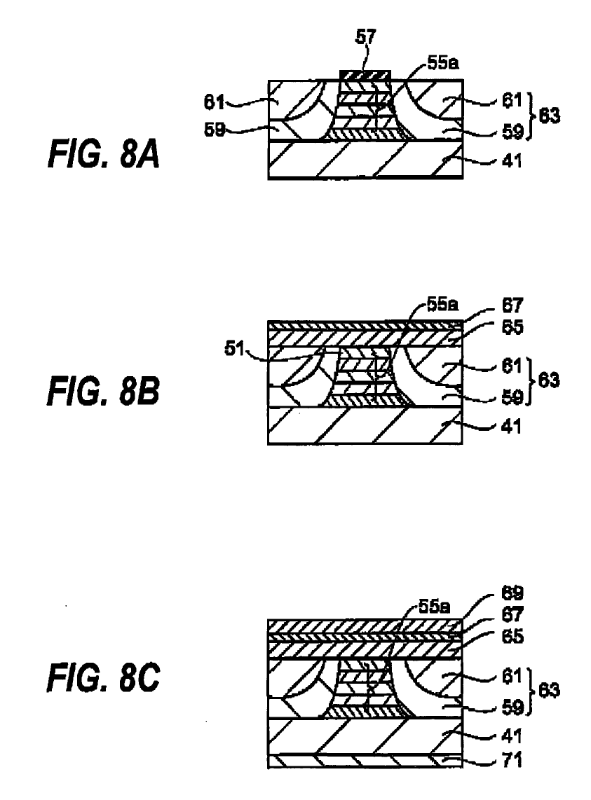

FIG. 6A shows a modification of the first embodiment of the present invention. The light-emitting device 1a provides the buried semiconductor region 115, the active region 105, the p-type III-V compound semiconductor region, and the n-type III-V compound semiconductor region. The buried region 115 includes the first p-type buried layer 109, the n-type buried layer 111 and the second p-type buried layer 113, and formed on the sides of the active region 105. The n-type III-V compound semiconductor region includes the first n-type cladding layer 107, the second n-type InP cladding layer 117 and the InGaAs contact layer 119. Similar to the first embodiment, the quantum well structure includes the first barrier layer 7 made of first III-V compound semiconductor material that includes aluminum, gallium, indium, and arsenic, and the quantum well layer 9 made of second III-V compound semiconductor material. The band gap energy of the first compound material is smaller than that corresponding to 1.0 μm, accordingly, the injection of the minority carrier, the electron in this configuration, into the p type buried layer 109 may be reduced, thereby preventing the thyristor comprised of the semiconductor regions of 101, 109, 111, 118, and 117 from turning on and the leak current from increasing.

FIG. 6B shows still another modification of the first embodiment. The light-emitting device 1b includes the active region 205, the buried region 213, the p-type III-V compound semiconductor region, and the n-type III-V compound semiconductor region, The buried semiconductor region 218 includes the n-type buried semiconductor layer 209 and the p-type buried semiconductor layer 211. These buried layers 213 and 209 are formed on the sides of the active region 206. The n-type III-V compound semiconductor layer includes the first n-type cladding layer 207, the second n-type InP cladding layer 215 and the InGaAe contact layer 217. The p-type III-V compound semiconductor layer includes the p-type InP substrate 101 and the p-type InP cladding layer 203. Similar to the first embodiment, the quantum well structure includes the first barrier layer 7 made of the first III-V compound semiconductor material including aluminum, gallium, indium and arsenic, and the quantum well layer 9 made of the second III-V compound semiconductor material. The active region 205 and the buried region 213 are disposed on the p-type III-V compound semiconductor region 101.

The sides of the active region 205 are covered by the p-type buried layer 211. The band gap energy of the first III-V compound material, which composes the first barrier layer 7, is smaller than that corresponding to the wavelength of 1.0 μm. Accordingly, the injection of the minority carrier, the electron in this case, into the first barrier layer 211 contacting thereto may be decreased, thereby preventing the thyristor with the pnpn structure comprised of semiconductor regions 101, 209, 211, and 216 from turning on and the leak current from increasing.

According to light-emitting devices 1, 1a and 1b, the active region includes a semiconductor layer made of AlGaInAs, in particular, includes the quantum well layer made of AlGaInAs with the emitting wavelength in the 1.8 μm band, and enables to reduce the leak current.

### Second Embodiment

From FIG. 7A to FIG. 7C show a method for manufacturing the light-emitting device, and from FIG. 5A to FIG. BB show the method for manufacturing the light-emitting device subsequently to those shown in FIG. 7.

As shown in FIG. 7A, a III-V compound semiconductor substrate 41 such as n-type InP substrate is prepared. A plurality of semiconductor layers, the n-type cladding layer 48 made of n-type InP layer, the lower SCH semiconductor layer 46 made of AlGaInAs layer, the multi-quantum well (MQW) region 47, the upper SCH layer 49 made of AlGaInAs, and the p-type cladding layer 51 made of p-type InP, are sequentially grown on the substrate 41. The growth of these layers may be carried out by using the Organo-Metallic Vapor Phase Epitaxy (OMVPE) apparatus 58. The MQW region 47 includes the AlGaInAs barrier layer, the band gap wavelength of which is between 1.05 μm and 1.15 μm, and the quantum well layer than has the band gap wavelength longer, for instance 1.4 μm, than that of the barrier layer.

As shown in FIG. 7B, a mask 57 is disposed on the stacked semiconductor layers 55 to form the semiconductor mesa. The mask 57 is made of dielectric material, for example, silicon nitride or silicon oxide. One example of the mask 57 has a width from 1 to 4 μm.

As shown in FIG. 7C, the semiconductor stripe 55a is etched by using the mask 57. This formation of the mesa 55a may be carried out by a dry etching, a wet etching or by both etching to the lowest semiconductor layer 43 so as to expose the substrate 41. The semiconductor stripe 55a includes the n-type cladding layer 48a, the lower SCH layer 45a, the MQW region 47a, the upper SCH layer 49a and the p-type cladding layer 51a.

Next, as shown in FIG. 8A, the buried region 63 will be formed. On the sides of the semiconductor stripe 51a and on the substrate 41 are formed with the p-type current blocking layer 69. The p-type current blocking layer 59 covers the sides of the lower SCH layer 46a, the MQW region 47a and the upper SCH layer 49a, and is grown so as to be in contact with at least a portion of the p-type cladding layer 51a. Subsequently, the n-type current blocking layer 61 is grown on the p-type current blocking layer 59. The growth of the p-type current blocking region 63 is grown without removing the mask 57. The current blocking region 63 buries the semiconductor stripe 55a, so the layer has a function of the buried region. After the growth of the current blocking layer, the mask 57 is removed.

On the buried region 68 is formed with the p-type cladding layer 65 such as p-type InP, as shown in FIG. 8B. Next, on the p-type cladding layer 65 is formed with the p-type contact layer 61 such as p-type InGaAs. Total thickness of the p-type cladding layer 51 and the p-type cladding layer 65 is about 2 μm.

On the p-type contact layer 67 is formed by a p-type ohmic electrode 69 made of stacked metals of Ti/Pt/Au. An n-type ohmic electrode 71 made of stacked metals of AuGe/Ni/Au is formed on the back surface of the substrate 41. The substrate 41 may be ground to about 100 μm before the formation of the n- and p-type electrodes.

According to the method thus described for manufacturing the semiconductor device, the light-emitting device may be obtained, in which the active layer includes an AlGaInAs semiconductor layer and the leak current is reduced. Further, although the present embodiment refers the light emitting device whose oscillation wavelength is in the 1.3 μm band, the invention may be applied to a light-emitting device whose emitting wavelength is in the 1.55 μm band.

The subjects of the present invention are explained as referring to accompanying drawings which shows preferred embodiments. However, it will be obvious for ordinal artisan in the field that the present invention has various modifications within the subjects of the invention. The present invention is not restricted to specified configurations disclosed in embodiments. For example, the light-emitting device may be a laser diode and a light-amplifying device. Accordingly, we claim all modifications and changes carried out within claims and within sprite of claims.

1. A semiconductor light-emitting device, comprising:
an active region having a quantum well structure formed by a first barrier layer made of a first III-V compound semiconductor material that contains aluminum, gallium, indium and arsenic, and a quantum well layer mad of a second III-V compound semiconductor material; and
a buried semiconductor region provided on sides of said quantum well layer,
wherein said first III-V semiconductor material has a band gap wavelength greater than 1 μm.

2. The semiconductor light-emitting device according to claim 1, wherein said first III-V semiconductor material has a band gap wavelength longer than 1.05 μm.

3. The semiconductor light-emitting device according to claim 1, wherein said second III-V compound semiconductor material contains aluminum, gallium, indium and arsenic.

4. The light-emitting device according to claim 1, further comprises a first buried layer having a first conduction type, said first buried layer being disposed on said buried semiconductor region,
wherein said buried semiconductor region has a second conduction type.

5. The light-emitting device according to claim 4, wherein said first buried layer is made of III-V compound semiconductor material containing indium and phosphorous, and
said buried region is made of III-V compound semiconductor material containing indium and phosphorous.

6. The light-emitting device according to claim 1, further comprises a III-V semiconductor region having a first conduction type and a III-V semiconductor region having a second conduction type,
wherein said active region and said buried region are disposed on said III-V compound semiconductor region with said first conduction type, and said III-V compound semiconductor region with said second conduction type is disposed on said active region and on said buried semiconductor region, and
wherein said active region including one or more second barrier layer, and said first barrier layer is nearer to said III-V compound semiconductor layer with said first conduction type than said second barrier layer.

7. The light-emitting device according to claim 1, further comprises a III-V compound semiconductor region with a first conduction type and a III-V compound semiconductor region with a second conduction type,
wherein said active region and said buried semiconductor region are disposed on said III-V compound semiconductor layer, and said III-V semiconductor layer with said second conduction type is disposed on said active region and on said buried semiconductor region,
wherein said active region includes an optical confinement layer disposed between said III-V compound semiconductor layer with said first conduction type and said quantum well layer, and
wherein a band gap wavelength of said optical confinement layer is smaller than a band gap wavelength of said first barrier layer.

8. The light-emitting device according to claim 1, further comprises
an InP substrate with a first conduction type,
a cladding layer with said first conduction type disposed on said InP substrate,
a cladding layer with second conduction type disposed on said InP substrate, and
